(19) United States
(12) Patent Application Publication
(10) Pub. No.: US 2024/0255562 A1
(43) Pub. Date: Aug. 1, 2024

(54) SYSTEMS AND METHODS FOR ESTIMATING QUIESCENT CURRENT IN POWER AMPLIFIER DIE

(71) Applicant: SKYWORKS SOLUTIONS, INC., Irvine, CA (US)

(72) Inventor: Shiban K. TIKU, Camarillo, CA (US)

(21) Appl. No.: 18/426,107

(22) Filed: Jan. 29, 2024

Related U.S. Application Data
(60) Provisional application No. 63/442,741, filed on Feb. 1, 2023.

(51) Int. Cl. G01R 31/26

(52) U.S. Cl. CPC G01R 31/2608; G01R 31/2644

(57) ABSTRACT

A computer-implemented method may determine a sheet resistance of a base layer of a bipolar junction transistor (BJT). A computer-implemented method may estimate a quiescent current based on the sheet resistance of the base layer. A computer-implemented method may reject a power amplifier die based on the quiescent current not satisfying a threshold level.

### CROSS-REFERENCE TO RELATED APPLICATION(S)

This application claims priority to U.S. Provisional Application No. 63/442,741 filed Feb. 1, 2023, entitled SYSTEMS AND METHODS FOR ESTIMATING QUIESCENT CURRENT IN POWER AMPLIFIER DIE AT PROBE TEST, the disclosure of which is hereby expressly incorporated by reference herein in its entirety.

### BACKGROUND

### Field

The present disclosure relates to improved systems and techniques for determining or estimating quiescent current of a component of a die during manufacturing or at probe test of the die.

### Description of the Related Art

Quiescent current is an important characteristic of a circuit/die. The quiescent current is the baseline current required to have circuit/die ready to perform its task—powered on but not yet in operation (e.g., a power amplifier ready to amplify but not actively amplifying a signal). An unacceptable level of quiescent current may indicate that a circuit/die may not be fit for use and, possibly, should be disposed. Efficient measurement of quiescent current can be challenging.

### SUMMARY

In accordance with a number of implementations, the present disclosure relates to a computer-implemented method including: determining a sheet resistance of a base layer of a bipolar junction transistor (BJT); estimating a quiescent current based on the sheet resistance of the base layer; and rejecting a power amplifier die based on the quiescent current not satisfying a threshold level.

In some aspects, the techniques described herein relate to a method wherein the rejecting the power amplifier die is performed as part of a probe test.

In some aspects, the techniques described herein relate to a method wherein the BJT is a heterojunction bipolar transistor (HBT).

In some aspects, the techniques described herein relate to a method wherein the HBT is a GaAs.

In some aspects, the techniques described herein relate to a method wherein the quiescent current is a collector quiescent current.

In some aspects, the techniques described herein relate to a method wherein the determining the sheet resistance further includes: providing a voltage supply pad connected to a first location of a base film; providing a measurement pad connected to a second location of the base film; measuring a voltage drop between the voltage supply pad and the measurement pad; measuring a current between the voltage supply pad and the measurement pad; and dividing the voltage drop with the current to determine a resistance.

In some aspects, the techniques described herein relate to a method wherein the determining the sheet resistance further includes: determining dimensions of the base film; and dividing the resistance with an aspect ratio associated with the dimensions.

In some aspects, the techniques described herein relate to a method wherein the estimating the quiescent current further includes determining a transistor beta for the BJT based on a correlation between the transistor beta and the sheet resistance.

In some aspects, the techniques described herein relate to a method wherein the correlation is determined based on a linear regression.

In some aspects, the techniques described herein relate to a method wherein the estimating the quiescent current further includes dividing the sheet resistance with a resistor configured to provide a base current to the BJT.

In some aspects, the techniques described herein relate to a system including: a processor; and a memory storing instructions that, when executed by the processor, causes the processor to perform steps including: determining a sheet resistance of a base layer of a bipolar junction transistor (BJT); estimating a quiescent current based on the sheet resistance of the base layer; and rejecting a power amplifier die based on the quiescent current not satisfying a threshold level.

In some aspects, the techniques described herein relate to a system wherein the rejecting the power amplifier die is performed as part of a probe test.

In some aspects, the techniques described herein relate to a system wherein the BJT is a heterojunction bipolar transistor (HBT).

In some aspects, the techniques described herein relate to a system wherein the HBT is a GaAs.

In some aspects, the techniques described herein relate to a system wherein the quiescent current is a collector quiescent current.

In some aspects, the techniques described herein relate to a system wherein the determining the sheet resistance further includes: providing a voltage supply pad connected to a first location of a base film; providing a measurement pad connected to a second location of the base film; measuring a voltage drop between the voltage supply pad and the measurement pad; measuring a current between the voltage supply pad and the measurement pad; and dividing the voltage drop with the current to determine a resistance.

In some aspects, the techniques described herein relate to a system wherein the determining the sheet resistance further includes: determining dimensions of the base film; and dividing the resistance with an aspect ratio associated with the dimensions.

In some aspects, the techniques described herein relate to a system wherein the estimating the quiescent current further includes determining a transistor beta for the BJT based on a correlation between the transistor beta and the sheet resistance.

In some aspects, the techniques described herein relate to a system wherein the estimating the quiescent current further includes dividing the sheet resistance with a resistor configured to provide a base current to the BJT.

In some aspects, the techniques described herein relate to a sheet resistance determination module including: a packaging substrate; a power amplifier die implemented on the packaging substrate, wherein the power amplifier die includes: a power amplifier, the power amplifier a bipolar junction transistor (BJT); a voltage supply pad coupled to a first location of a base of the BJT, the voltage supply pad configured to apply a first voltage to the first location; and a measurement pad coupled to a second location of the base, the measurement pad configured to measure a second voltage that is the first voltage minus a resistance multiplied by a base current.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates an example NPN-type BJT in accordance with one or more embodiments.

FIG. 2 illustrates an example cross-sectional view of an HBT in accordance with one or more embodiments.

FIGS. 3A-3B illustrate an example relationship between transistor beta and sheet resistance of the base layer in accordance with one or more embodiments.

FIG. 4 illustrates an example test structure that can be added to a die to improve measurement and testability of collector quiescent current in accordance with one or more embodiments.

FIG. 5 illustrates an example flow diagram of a process to examine a die for quiescent current in accordance with one or more embodiments.

FIG. 6 illustrates an example sheet resistance determination module in accordance with one or more embodiments.

FIG. 7 illustrates an example radio-frequency device in accordance with one or more embodiments.

### DETAILED DESCRIPTION OF SOME EMBODIMENTS

The present disclosure relates to improved systems and techniques for determining or estimating quiescent current of a power amplifier (PA) in a radio-frequency (RF) front-end (FE) architecture. In radio-frequency (RF) applications, an RF signal to be transmitted is typically generated by a transceiver. Such an RF signal can then be amplified by a power amplifier (PA), and the amplified RF signal can be routed to an antenna for transmission. One important characteristic of a PA is the quiescent current.

The quiescent current can be defined as the amount of current used by a circuit/die, such as a PA integrated circuit (IC) or a PA die, when the circuit/die is in its quiescent state. The quiescent state is any period of time when the circuit/die is enabled but not amplifying a signal or driving a load. That is, the quiescent current is the baseline current required to have the circuit/die ready to perform its task—powered on but not yet in operation. Intuitively, the quiescent state can be analogized to a microphone that is turned on, drawing current (i.e., quiescent current), ready to amplify a received signal, but have not yet received the signal. Similarly, a PA of an RFFE can be drawing quiescent current when the PA is ready to amplify and transmit a signal, but not yet transmitting any signal.

The quiescent current is important for a PA for multiple reasons including energy efficiency, output power, linearity, et cetera. Energy efficiency as an example, when a device containing the PA operates on a battery, a smaller quiescent current will cause the device to outlast a different device with a PA associated with a larger quiescent current, provided all else are equal. The difference can make the battery last months as opposed to mere weeks.

Acceptable levels of quiescent current is set in design and must be within specified limits or threshold levels. When quiescent current is too large, the circuit to be out of acceptable specification unable to satisfy critical functional parameters such as energy efficiency, output power, linearity, or the like. Since RF module costs for mobile applications are high, a circuit/die that going to have out-of-specification quiescent current should be screened out. Unfortunately, it can be challenging to determine quiescent current of a circuit/die, thereby complicating screening of the out-of-spec circuit/die. This is because quiescent current of a circuit can vary significantly due to multiple factors that are not easily controlled, including epitaxial structural variation and manufacturing process variations. Additionally, oscillation can occur for a PA circuit/die and addressing such oscillation further complicates quiescent current determination. The problem of accurately determining quiescent current has existed for over a decade and is difficult to solve.

Conventionally, methods using highly complex probes and test systems that solve the problem of oscillation have been developed to measure quiescent current. However, the conventional methods have been tried with very little success at least partly due to difficulty in measuring transistor parameters, such as transistor beta (p). Quiescent current is generally determined by the transistor beta (β) and resistors used to set a current. For example, collector quiescent current (i_{cq}) of a bipolar junction transistor (BJT), including heterojunction bipolar transistor (HBT) of GaAs or lil-V PAs, may be determined based on its transistor beta (β) and transistors used to set its base current (i). However, the transistor beta (p) cannot be measured die by die and is generally measured in process control monitors (PCM). Additionally, quiescent current measurements at die probe test are very difficult to implement at wafer test because of oscillation. Therefore, there exists a need for a much simpler and perhaps indirect method of measuring quiescent current.

An improved approach disclosed herein proposes a solution that can an indirectly determine quiescent current to reject (or ink out) a bad circuit/die. The proposed solution can determine whether the quiescent current of the circuit/die is too high or too low. In some embodiments, the proposed solution can add a test structure to the circuit/die along with other design elements that may be added for improved testability. Advantageously, the proposed solution does not involve sophisticated probes that require exceptional care to reduce errors and is easy to implement with minimal area added to a die.

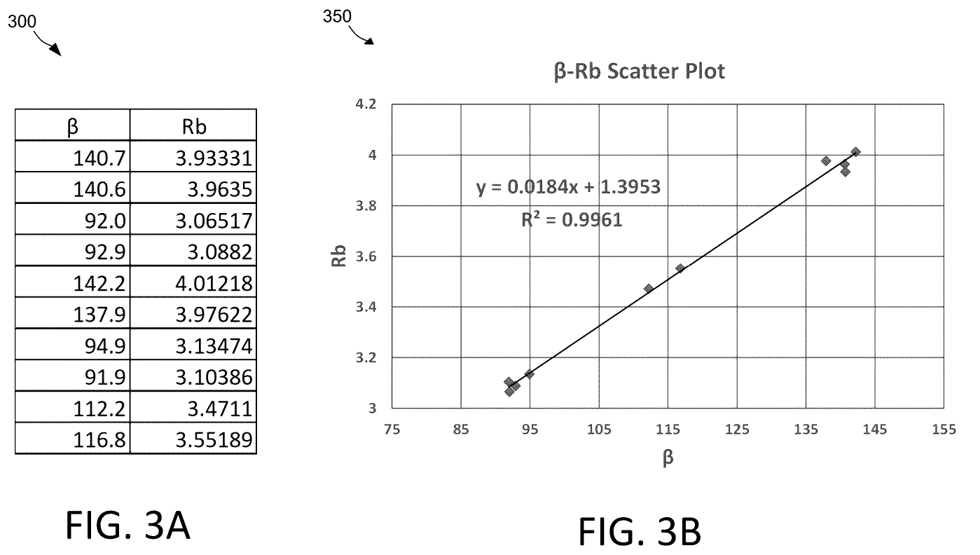

The proposed solution observes and relies on a correlation between a transistor beta (p), such as a HBT beta, and sheet resistance of the base layer (R_{b}) of the transistor structure, such as the HBT structure. The present disclosure observes that the epitaxial structure and transistor device design is such that the transistor beta (p) exhibits a linear correlation with R_{b}, regardless of doping and thickness variations. The correlation will be described in greater detail with FIGS. 3A-3B. Therefore, a base resistor can be used to represent the HBT beta and the resistors can be represented by the type of resistor that is used in the bias circuit, which can be denoted R_{L}. It will be shown that the ratio of R_{b} to R_{L} can represent the collector quiescent current (i_{cq}), thereby providing a simpler technique of determining/estimating the i_{cq}. Accordingly, the proposed solution provides an indirect method to estimate the i_{cq} during a probe test, such as a wafer D.C. probe test, which can greatly simplify a determination whether a PA die is within an acceptable specification.

The systems and techniques are discussed herein in the context of power amplifiers for wireless communication devices. However, it is noted that the systems and techniques can be applied to a wide variety of applications and circuits/dies. Further, the present disclosure illustrates and describes various BJTs, specifically HBTs. However, any type of transistor may be used instead of the HBTs for the teachings of the present disclosure where applicable. Additionally, It is noted that, while PAs are provided in the present disclosure as example circuit/die/components, the systems, methods, and techniques disclosed herein may be applied to any circuit/die/component with quiescent current.

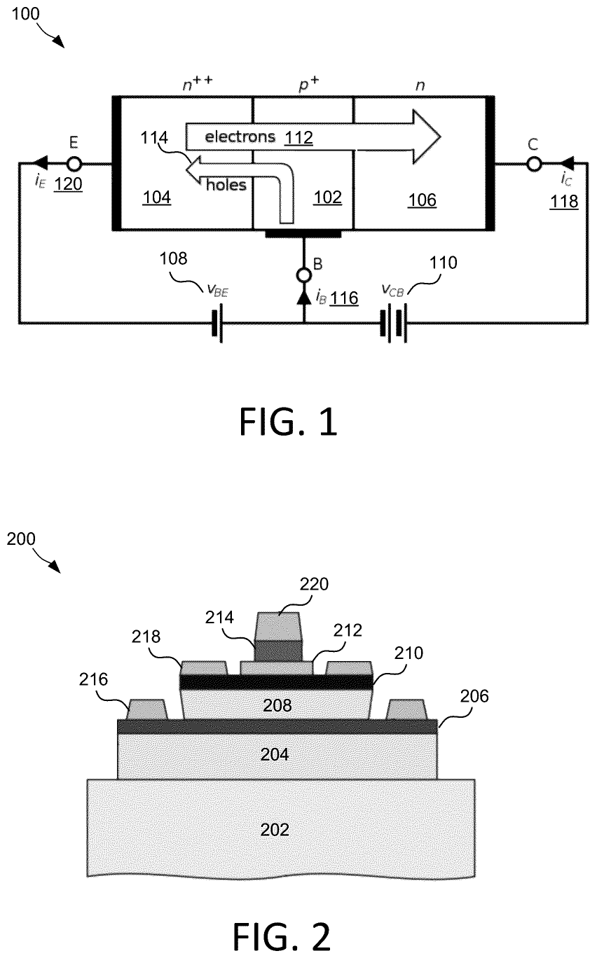

FIG. 1 illustrates an example NPN-type BJT 100 in accordance with one or more embodiments. The BJT 100 may be an HBT in some implementations. The BJT 100 can include a base region 102, an emitter region 104, and a collector region 106. As illustrated, in an NPN transistor, these regions are, respectively, p type, n type and n type. Each semiconductor region 102, 104, 106 is respectively connected to a corresponding terminal: base (B) 116, emitter (E) 120, and collector (C) 118.

The BJT 100 can be applied bias voltages to configure the BJT 100 in a quiescent state ready to provide, but not yet providing its function. In the BJT 100, a base-emitter voltage (V_{BE}) 108 can apply a forward bias voltage to the base-emitter junction. A collector-base voltage (V_{CB}) 110 can apply a reverse bias voltage to the collector-base junction. The applied voltages, V_{BE} 108 and V_{CB} 110, can cause electrons 112 to flow from the emitter region 104 through the base region 102 to the collector region 106, thereby causing a collector current (i_{c}) 118 to flow from the collector to the emitter. Similarly, holes 114 can flow from the base region 102 to the emitter region 104, thereby causing a base current (i_{b}) 116 to flow from the base to the emitter. The emitter can receive the base current (i_{b}) 116 and the collector current (i_{c}) 118 and output an emitter current (iₑ) 120.

As mentioned, quiescent current can be determined by a transistor beta (3) and resistors used to set a current, such as a base current. The transistor beta (β) is generally defined as a ratio between the base current (i_{b}) and a collector current (i_{c}):

$$β = \frac{{i}_{c}}{{i}_{b}} . \qquad ( Equation 1 )$$

Where quiescent current is concerned, the currents are collector quiescent current and base quiescent current, giving us a more specific equation:

$${β}_{q} = \frac{{i}_{cq}}{{i}_{bq}} . \qquad ( Equation 2 )$$

Rearranging the equation provides an equation for the collector quiescent current:

$${i}_{cq} = {β}_{q} * {i}_{bq} . \qquad ( Equation 3 )$$

Thus, if the base quiescent current (i_{bq}) and the transistor beta in the quiescent state (β_{q}) can be determined or estimated, then the collector quiescent current (i_{cq}) may also be determined or estimated. These equations will be explored in greater detail below.

It will be understood that the NPN-type BJT 100 is one embodiment of a transistor and not to be considered limiting. For example, different structures/configurations of BJTs, such as PNP-type transistors, or different types of transistors, such as field-effect transistors (FETs) may be used for the present disclosure where appropriate. Further, based on expected functionality of the transistor, different biasing may be applied to its terminals.

FIG. 2 illustrates an example cross-sectional view 200 of an HBT in accordance with one or more embodiments. The HBT can be the example BJT 100 of FIG. 1 and, more specifically, GaAs or III-V PA. The HBT can include multiple layers, which may include some or all of:
A semi-insulating substrate layer 202 on which epitaxial layers are formed.
A subcollector layer 204 meant to provide a high conductivity interface to a collector 208.
A contact layer 206.
The collector 208, which may be lightly doped.
A base 210, which may be heavily doped to reduce base resistance and thin depth to reduce base transit time.
An emitter 212, which may be lightly doped compared to the base 210.
An emitter cap 214, which may provide a high-conductivity interface to the emitter 212.

Each of the collector 208, base 210, and the emitter 212 can be coupled with a collector electrode 216, base electrode 218, and emitter electrode 220, respectively. Importantly, during fabrication of the HBT, dimensions (e.g., width, length, area, thickness, or the like) can be controlled for the collector 208, base 210, and/or emitter 212.

It will be understood that various layers and components depicted in the example view 200 are examples and not to be considered limiting. The layers and components may be implemented with various materials, thicknesses, and/or doping.

FIGS. 3A-3B illustrate an example relationship between transistor beta (p) and sheet resistance of the base layer (R_{b}) in accordance with one or more embodiments. Sheet resistance, also known as surface resistance or surface resistivity, is an electrical property used to characterize thin films of conducting and semiconducting materials. It is a measure of the lateral resistance through a thin square of material. That is, it is the resistance between opposite sides of a square and has a unit of “ohms per square” (denoted “Ω/sq” or “Ω/□”). The sheet resistance is independent of the size of the square if the thin film measured is of the same material and thickness. The sheet resistance can often be easily measured during a probe test, such as a wafer direct current probe test. In some embodiments, test structures including test pads and/or electrodes can be added to the die to facilitate the measurement of the sheet resistance of the base layer (R_{b}). The present disclosure observes that the transistor beta (β) and sheet resistance of the base layer (R_{b}) exhibits a linear correlation regardless of doping and thickness variations.

For instance, FIG. 3A shows a table 300 with a first column with various observed transistor betas (β) and a second column with corresponding measured sheet resistances of the base layers (R_{b}). FIG. 3B shows the values plotted on a scatter plot 350. In the scatter plot 350, X-axis provides a range of transistor betas (β) and Y-axis provides sheet resistances of the base layers (R_{b}). Further, FIG. 3B shows a linear regression line on the scatter that highlights a close correlation between the values. For the given samples listed in the table 300, the linear regression follows a formula “y=0.0184x+1.3953” with a R² value 0.9961. Accordingly, when a sheet resistance of the base layer (R_{b}) of a BJT, such as an HBT, can be known, it is possible to estimate the transistor beta (β) for the BJT. The transistor beta (β) can widely vary between ranges from 50 to 200 not just from a die to another die but based on operating conditions and it can be challenging to measure the transistor beta (β). In contrast, the sheet resistance of the base layer (R_{b}) may be much simpler and easier to measure.

The sheet resistance of the base layer (R_{b}) can be used to screen out dies based on transistor betas (β) estimated with the correlation. For example, for the correlation in the scatter plot 350, an acceptable transistor beta (β) may range between 90 to 110. According to the linear regression, the transistor beta (β) range corresponds to the sheet resistance of the base layer (R_{b}) range of 3.0513 to 3.4193 kOhm/sq. A measured sheet resistance of the base layer (R_{b}) can be compared to the acceptable range to determine whether to accept or to reject a die. In some implementations, the acceptable range can be specified as one or more threshold levels of sheet resistance of the base layer (R_{b}) or the transistor beta (β).

In some embodiments, a collector quiescent current (i_{cq}) determined or estimated based on the correlation. A base quiescent current (i_{bq}) can be set by at least one biasing resistor that provides a bias current, for example, such as the bias current i_{b}116 in the BJT 100 of FIG. 1. Here, the biasing resistor in a bias circuit used to set the bias current can be denoted R_{L}. Using the notations, the bias current can be calculated as a supply voltage (V_{supply}) to the bias circuit divided by the biasing resistor according to the following equation:

$${i}_{bq} = \frac{{V}_{supply}}{{R}_{L}} . \qquad ( Equation 4 )$$

Thus, it can be seen that the base quiescent current (i_{bq}) is proportional to the supply voltage (V_{supply}) and inversely-proportional to the biasing resistor (R_{L}).

Referring back to FIGS. 3A-3B, it was mentioned that the sheet resistance of the base layer (R_{b}) proportionally correlates with the transistor beta (β):

$${β}_{q} ∝ {R}_{b} . \qquad ( Relationship 1 )$$

Relating the above relationships with the Equation 3, we have the following relationship:

$${i}_{cq} ∝ \frac{{R}_{b}}{{R}_{L}} . \qquad ( Relationship 2 )$$

Thus, the ratio of R_{b} to R_{L} can estimate the collector quiescent current (i_{cq}). The estimation of the collector quiescent current (i_{cq}) involves a determination of the sheet resistance of the base layer (R_{b}), which can easily be determined during probe test, and a known biasing resistor (R_{L}) value. Accordingly, the observed correlation opens up a new indirect and simpler technique for determining/estimating the collector quiescent current (i_{cq}). In order to enable ready measurement of the sheet resistance of the base layer (R_{b}), the present disclosure contemplates providing test structures on a PA die.

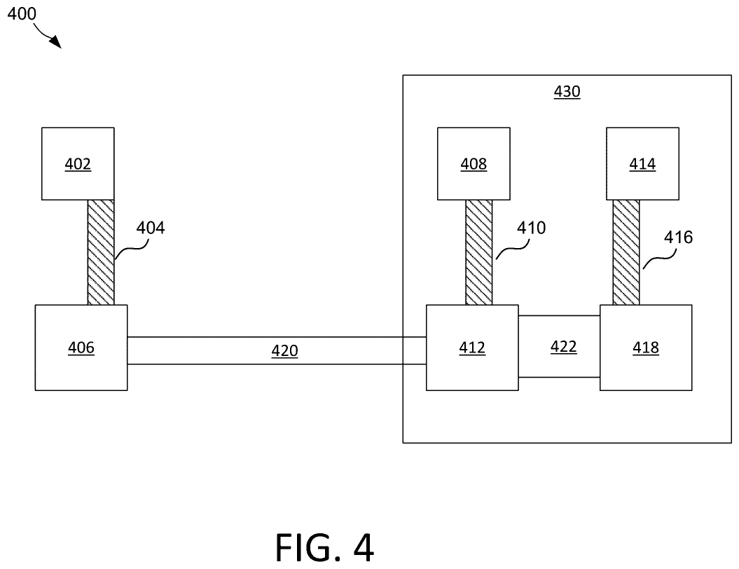

FIG. 4 illustrates an example test structure 430 that can be added to a die 400, such as a PA die, to improve measurement and testability of collector quiescent current (i_{cq}) in accordance with one or more embodiments. In the die 400, a ground pad 402 can connect to a ground electrode 406 with a ground connection 404, a measurement pad 408 can connect to a first base electrode 412 with a first base connection 410, a test voltage supply pad 414 can connect to a second base electrode 418 with a second base connection 416. In some implementations, the pads 402, 408, 414 can be provided on a backside (or opposing side of the electrodes 406, 412, 418) of the die 400.

At least one biasing resistor (R_{L}) 420 can connect the ground electrode 406 and the first base electrode 412 to provide a base current (i_{b}). When the die 400 is operating in the quiescent state, the base current (i_{b}) may be the base quiescent current (i_{bq}). Generally, determination of the base quiescent current (i_{bq}) can involve application of the Equation 4 with known values of the biasing resistor (R_{L}) and a supply voltage (V_{supply}), which may be performed during a probe test. The biasing resistor (R_{L}) 420 can be selected to have a resistance value that would forward bias the base-emitter junction and reverse bias the collector-emitter junction, as described in relation to the example BJT 100 of FIG. 1, to operate the die in its quiescent state. In some instances, the biasing resistor (R_{L}) may be implemented as a resistive trace having the same width as actual circuit die.

As mentioned, a test structure 430 can be added to the die 400.

Specifically, the added test structure 430 can facilitate measurement of sheet resistance of the base layer (R_{b}) across a base film 422, such as the base 210 of FIG. 2, of the die 400. The test structure 430 can include some or all of the measurement pad 408, the first base connection 410, first base electrode 412, test voltage supply pad 414, second base connection 416, and second base electrode 418. The first base electrode 412 can be attached to an edge (or closer to the edge at a first location) of the base film 422 and the second base electrode 418 can be attached to an opposing edge (or closer to the opposing edge at a second location) of the base film 422.

During a measurement of the sheet resistance of the base layer (R_{b}), a test voltage (Vₜₑₛₜ) can be provided to the test voltage supply pad 414 which, via the second base connection 416, applies the test voltage (Vₜₑₛₜ) to the second base electrode 418. The test voltage (Vₜₑₛₜ) can cause a current to flow through the base film 422, thereby dropping in voltage. The resulting voltage (V_{measured}) after the drop can be measured at the measurement pad 408 through its first base connection 410 to the first base electrode 412.

A resistance the base film 422 can be measured by dividing the voltage drop between the test voltage (Vₜₑₛₜ) and the measured voltage (V_{measured}) with a test current (iₜₑₛₜ) between the first and second electrodes 412, 418 according to below equation:

$${R}_{base} = \frac{{V}_{test} - {V}_{measured}}{{i}_{test}} . \qquad ( Equation 5 )$$

The base film 422 can have known dimensions of width, length, and thickness controlled during fabrication of the die 400. Accordingly, for the dimensions, a minimum or any convenient width, length, and thickness can be used for fabrication of the base film 422. The sheet resistance of the base layer (R_{b}) can be computed based on the known dimensions (e.g., aspect ratio). For example, a 3-unit long by 1-unit wide sheet has an aspect ratio of 3 (i.e., 3-unit divided by 1-unit). If Rₜₒₜₐₗ is 9.3 kOhm, then the sheet resistance of the base layer (R_{b}) is 3.1 kOhm/sq according to below formula of sheet resistance:

$${R}_{b} = \frac{{R}_{base}}{Aspect ratio} . \qquad ( Equation 6 )$$

Since R_{L} and R_{b} are determinable, the collector quiescent current (i_{cq}) can be indirectly determined/estimated based on the Relationship 2 described above.

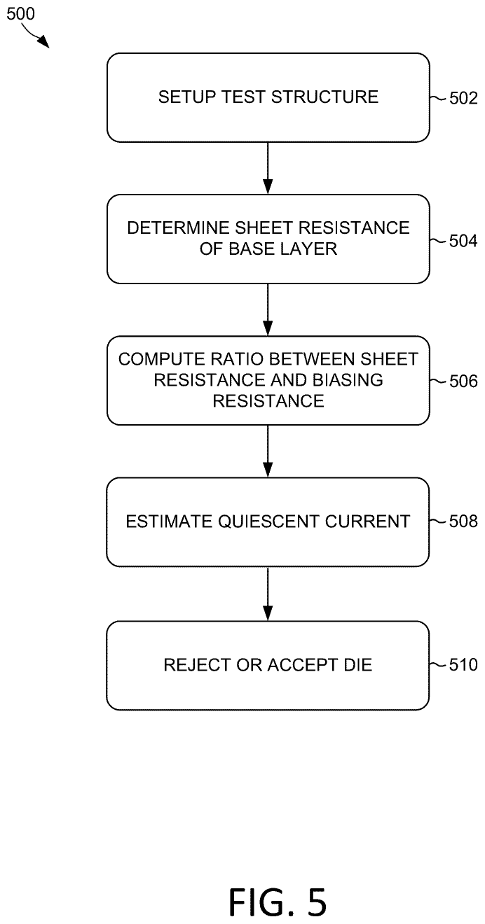

FIG. 5 illustrates an example flow diagram of a process 500 to examine a die for quiescent current in accordance with one or more embodiments. The process 500 can be implemented as part of a probe test, such as a wafer D.C. probe test, or as part of any applicable test. In some embodiments, the process 500 can be implemented at a computing device, such any computing system with a software implementing the process 500.

At block 502, a test structure can be setup. The test structure can be the test structure 430 of FIG. 4. Setting up the test structure can involve adding one or more test pads, such as the measurement pad 408 and the test voltage supply pad 414, and related structures/components, such as the first base connection 410, first base electrode 412, second base connection 416, and second base electrode 418 to a circuit/die.

At block 504, sheet resistance of the base layer (R_{b}) can be determined. As mentioned, the determination of the sheet resistance of the base layer (R_{b}) can involve test applying a test voltage (Vₜₑₛₜ) at the test voltage supply pad 414, measuring a voltage (V_{measured}) at the measurement pad 408, and computing the sheet resistance of the base layer (R_{b}) using the Equations 5 and 6.

At block 506, a ratio between the sheet resistance of the base layer (R_{b}) and biasing resistance (R_{L}) can be computed.

At block 508, quiescent current can be estimated. The quiescent current can be the collector quiescent current (i_{cq}). The estimated quiescent current can rely on the ratio computed at the block 506 based on the Relationship 2. In some embodiments, the estimated quiescent current can be a multiple of the base quiescent current (i_{bq}) computed based on the Equation 4 and a transistor beta (β) estimated based on the correlation examined in FIGS. 3A-3B.

At block 510, a die can be accepted or rejected based on the quiescent current estimated at the block 508. In some embodiments, the die can be rejected based on the sheet resistance of the base layer (R_{b}) determined at the block 504 alone. In some other embodiments, the die can be rejected based on the transistor beta (β) estimated at the block 508 alone. In some implementations, the acceptable range can be specified as one or more threshold levels of the quiescent current or the R_{b}/R_{L}.

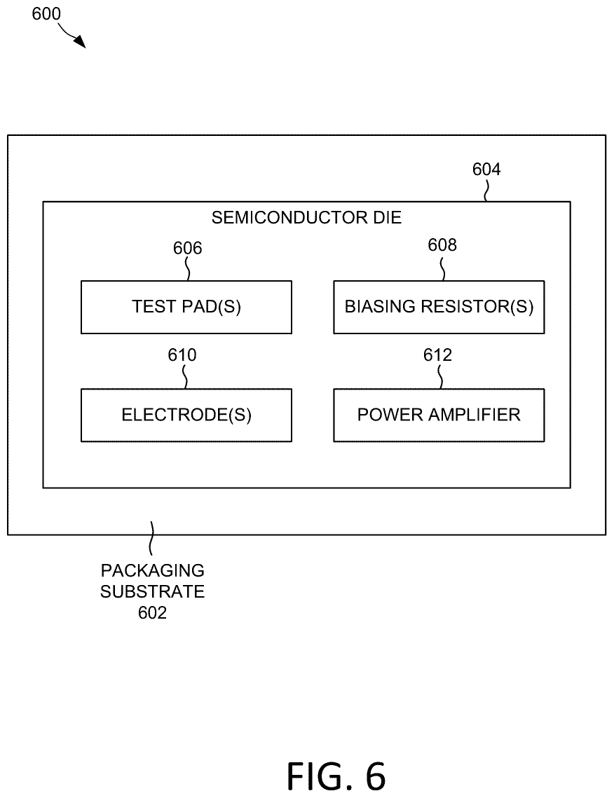

FIG. 6 illustrates an example sheet resistance determination module 600 in accordance with one or more embodiments. The sheet resistance determination module 600 includes a packaging substrate 602, a semiconductor die 604 mounted on the packaging substrate 602, one or more test pad(s) 606 implemented on the semiconductor die 604, one or more biasing resistor(s) 608 implemented on the semiconductor die 604, one or more electrode(s) 610 implemented on the semiconductor die 604, and a power amplifier 612 implemented on the semiconductor die 604. The test pad(s) 606 can include any of the test pads discussed herein, the biasing resistor(s) 608 can include any of the biasing resistors discussed herein, the electrode(s) 610 can include any of the electrodes discussed herein, and/or the power amplifier 612 can include any of the PAs discussed herein, including a BJT/HBT PA. Although the power amplifier 612 is illustrated as being implemented on the semiconductor die 604 and the packaging substrate 602, the power amplifier 612 can be implemented on a separate semiconductor die and/or packaging substrate. Similarly, the test pad(s) 606, the biasing resistor(s) 608, and the electrode(s) 610 can be implemented on separate semiconductor dies and/or packaging substrates. In some embodiments, the sheet resistance determination module 600 can be a front-end module (FEM), which can include a diversity module (e.g., a diversity-receive module) in some examples.

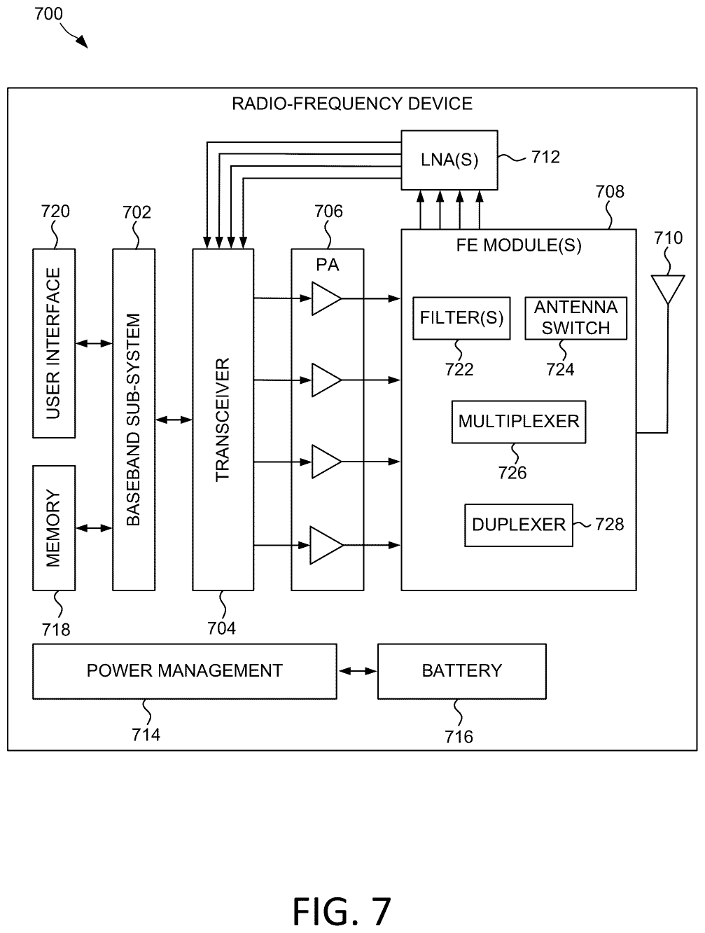

FIG. 7 illustrates an example radio-frequency device 700 in accordance with one or more embodiments. As shown, the radio-frequency device 700 can include a baseband sub-system 702, a transceiver 704, a power amplifier (PA) module 706, one or more front-end (FE) modules 708, one or more antennas 710, one or more low noise amplifiers (LNAs) 712, a power management system (module) 714, a battery 716, a memory 718, and a user interface 720. The baseband sub-system 702, the transceiver 704, the PA module 706, the one or more FE modules 708, the one or more antennas 710, the one or more LNAs 712, the power management system 714, the battery 716, the memory 718, and/or the user interface 720 can be in communication with each other.

The baseband sub-system 702 can be connected to the user interface 720 to facilitate various input and/or output of voice and/or data provided to and/or received from a user. The baseband sub-system 702 can also be connected to the memory 718 that is configured to store data and/or instructions to facilitate operation of the radio-frequency device 700 and/or to provide storage of information for a user.

The transceiver 704 can generate radio-frequency (RF) signals for transmission and/or process incoming RF signals received from the one or more LNAs 712, the one or more antennas 710, and/or the one or more FE modules 708. The transceiver 704 can interact with the baseband sub-system 702 that is configured to provide conversion between data and/or voice signals suitable for a user and/or RF signals suitable for the transceiver 704. The transceiver 704 can also be connected to the power management system 714.

The PA module 706 can include a plurality of PAs that can provide an amplified RF signal to the one or more antennas 710, such as via one or more components of the one or more FE modules 708. Although four paths are shown as inputs and outputs to the PA module 706, and any number of input and/output paths can be implemented.

The one or more FE modules 708 can include one or more filters 722, an antenna switch 724, a multiplexer 726, and/or a duplexer 728. The one or more filters 722 can include receive (Rx) filters and/or transmit (Tx) filters. In some embodiments, one or more of the one or more filters 722 are implemented as part of a combined band filter circuit, such as any of the combined band filter circuits discussed herein, which can include one or more switches for routing signals in some examples. The antenna switch 724 can route a signal to and/or from the one or more antennas 710, such as to and/or from other components of the one or more FE modules 708. The antenna switch 724 can include any number of poles and/or throws. In some embodiments, the antenna switch 724 is implemented as part of a module. The multiplexer 726 can be configured to implement multiplexing. The duplexer 728 can allow transmit and/or receive operations to be performed simultaneously using a common antenna. In some embodiments, the one or more FE modules 708 can route one or more received signals to the one or more LNAs 712, which can be configured to amplify the one or more received signals. In some embodiments, the packaged module 708 is implemented as a front-end module. Although the one or more LNAs 712 and the PA module 706 are illustrated as separate components from the one or more FE modules 708, in some embodiments the one or more LNAs 712 and/or the PA module 706 are part of the one or more FE modules 708.

The one or more antennas 710 can include antennas for transmitting and/or receiving signals associated with a wide variety of frequencies and communications standards. In examples, the one or more antennas 710 support Multiple-Input Multiple-output (MIMO) communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity can refer to communications in which a particular antenna is selected for operation at a particular time. For example, a switch can be used to select a particular antenna from a group of antennas based on a variety of factors, such as an observed bit error rate and/or a signal strength indicator. In examples, the one or more antennas 710 can include a diversity antenna.

The power management system 714 can be configured to manage power for operation of the radio-frequency device 700. The power management system 714 can provide power to any number of components of the radio-frequency device 700. The power management system 714 can receive a battery voltage from the battery 716. The battery 716 can be any suitable battery for use in the radio-frequency device 700, including, for example, a lithium-ion battery. Any of the circuits and their configurations disclosed herein can be implemented for, or as a part of, the power management system 714.

The radio-frequency device 700 can communicate using a wide variety of communications technologies, including, but not limited to, 2G, 3G, 4G (including Long Term Evolution (LTE), LTE-Advanced, and LTE-Advanced Pro), 5G, Wireless Local Area Network (WLAN) (for instance, Wi-Fi), Wireless Personal Area Network (WPAN) (for instance, Bluetooth and ZigBee), Wireless Metropolitan Area Network (WMAN) (for instance, WiMax), and/or satellite-based radio navigation systems (for instance, Global Positioning System (GPS) technologies).

The radio-frequency device 700 can operate with beamforming in certain implementations. For example, the radio-frequency device 700 can include phase shifters having variable phase controlled by the transceiver 704. Additionally, the phase shifters can be controlled to provide beam formation and directivity for transmission and/or reception of signals using the one or more antennas 710. For example, in the context of signal transmission, the phases of the transmit signals provided to the one or more antennas 710 are controlled such that radiated signals from the one or more antennas 710 combine using constructive and destructive interference to generate an aggregate transmit signal exhibiting beam-like qualities with more signal strength propagating in a given direction. In the context of signal reception, the phases are controlled such that more signal energy is received when the signal is arriving to the one or more antennas 710 from a particular direction. In some embodiments, the one or more antennas 710 include one or more arrays of antenna elements to enhance beamforming.

In some embodiments, the radio-frequency device 700 supports carrier aggregation, thereby providing flexibility to increase peak data rates. Carrier aggregation can be used for both Frequency Division Duplexing (FDD) and Time Division Duplexing (TDD) and can be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The radio-frequency device 700 can include a wide variety of devices that are configured to communicate wirelessly. For example, the radio-frequency device 700 can include a cellular phone, a smart-phone, a hand-held wireless device with or without phone functionality, a wireless tablet, a smart appliance, a smart vehicle, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wearable device (e.g., a watch), a clock, etc.

The detailed description is set forth with reference to the accompanying figures. In the figures, the left-most digit(s) of a reference number identifies the figure in which the reference number first appears. The use of the same reference numbers in different figures indicates similar or identical items.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled” can refer to two or more elements that may be either directly connected or connected by way of one or more intermediate elements. Components discussed herein can be coupled in a variety of manners, such as through a conductive material. Additionally, the words “herein,” “above,” “below,” and words of similar import, when used in this disclosure, shall refer to this application as a whole and not to any particular portions of this application. Where the context permits, words in the above Description using the singular or plural number may also include the plural or singular number respectively.

The above description of embodiments of the disclosure is not intended to be exhaustive or to limit the disclosure to the precise form disclosed above. While specific embodiments, and examples, are described above for illustrative purposes, various equivalent modifications are possible within the scope of the disclosure, as those skilled in the relevant art will recognize. For example, while processes or blocks can be presented in a given order, alternative embodiments can perform routines having steps, or employ systems having blocks, in a different order, and some processes or blocks can be deleted, moved, added, subdivided, combined, and/or modified. Each of these processes or blocks can be implemented in a variety of different ways. Also, while processes or blocks are at times shown as being performed in series, these processes or blocks can instead be performed in parallel or can be performed at different times.

The features described herein can be applied to other systems, not necessarily the system described above. The elements and acts of the various embodiments described above can be combined to provide further embodiments.

In some embodiments, the methods and/or systems discussed herein can be implemented at least in part by control circuitry and/or memory. For example, memory can store executable instructions that, when executed by control circuitry, cause the control circuitry to perform operations discussed herein. Additionally, or alternatively, other methods and/or systems discussed herein can be implemented at least in part with control circuitry and memory storing executable instructions.

Control circuitry can include one or more processors, such as one or more central processing units (CPUs), one or more microprocessors, one or more graphics processing units (GPUs), one or more digital signal processors (DSPs), and/or other processing circuitry. Alternatively, or additionally, control circuitry can include one or more application specific integrated circuits (ASIC), one or more field-programmable gate arrays (FPGAs), one or more program-specific standard products (ASSPs), one or more complex programmable logic devices (CPLDs), and/or the like. Control circuitry can be configured to execute one or more instructions stored in memory to thereby perform one or more operations to implement various functionality discussed herein.

Memory can include any suitable or desirable type of computer-readable media. For example, computer-readable media can include one or more volatile data storage devices, non-volatile data storage devices, removable data storage devices, and/or nonremovable data storage devices implemented using any technology, layout, and/or data structure(s)/protocol, including any suitable or desirable computer-readable instructions, data structures, program modules, or other types of data. Computer-readable media that may be implemented in accordance with embodiments of the present disclosure includes, but is not limited to, phase change memory, static random-access memory (SRAM), dynamic random-access memory (DRAM), other types of random access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transitory medium that can be used to store information for access by a computing device. As used in certain contexts herein, computer-readable media may not generally include communication media, such as modulated data signals and carrier waves. As such, computer-readable media should generally be understood to refer to non-transitory media.

While some embodiments have been described, these embodiments have been presented by way of example only, and are not intended to limit the scope of the disclosure. Indeed, the methods and systems described herein can be embodied in a variety of other forms; furthermore, various omissions, substitutions and changes in the form of the methods and systems described herein can be made without departing from the spirit of the disclosure. Claims and their equivalents are intended to cover such forms or modifications as would fall within the scope and spirit of the disclosure.

What is claimed is:

1. A computer-implemented method comprising:
determining a sheet resistance of a base layer of a bipolar junction transistor (BJT);
estimating a quiescent current based on the sheet resistance of the base layer; and
rejecting a power amplifier die based on the quiescent current not satisfying a threshold level.

2. The method of claim 1 wherein the rejecting the power amplifier die is performed as part of a probe test.

3. The method of claim 1 wherein the BJT is a heterojunction bipolar transistor (HBT).

4. The method of claim 3 wherein the HBT is a GaAs.

5. The method of claim 1 wherein the quiescent current is a collector quiescent current.

6. The method of claim 1 wherein the determining the sheet resistance further comprises:
providing a voltage supply pad connected to a first location of a base film;
providing a measurement pad connected to a second location of the base film;
measuring a voltage drop between the voltage supply pad and the measurement pad;
measuring a current between the voltage supply pad and the measurement pad; and
dividing the voltage drop with the current to determine a resistance.

7. The method of claim 6 wherein the determining the sheet resistance further comprises:
determining dimensions of the base film; and
dividing the resistance with an aspect ratio associated with the dimensions.

8. The method of claim 1 wherein the estimating the quiescent current further comprises determining a transistor beta for the BJT based on a correlation between the transistor beta and the sheet resistance.

9. The method of claim 8 wherein the correlation is determined based on a linear regression.

10. The method of claim 1 wherein the estimating the quiescent current further comprises dividing the sheet resistance with a resistor configured to provide a base current to the BJT.

11. A system comprising:
a processor; and
a memory storing instructions that, when executed by the processor, causes the processor to perform steps comprising:
determining a sheet resistance of a base layer of a bipolar junction transistor (BJT);
estimating a quiescent current based on the sheet resistance of the base layer; and
rejecting a power amplifier die based on the quiescent current not satisfying a threshold level.

12. The system of claim 11 wherein the rejecting the power amplifier die is performed as part of a probe test.

13. The system of claim 11 wherein the BJT is a heterojunction bipolar transistor (HBT).

14. The system of claim 13 wherein the HBT is a GaAs.

15. The system of claim 11 wherein the quiescent current is a collector quiescent current.

16. The system of claim 11 wherein the determining the sheet resistance further comprises:
providing a voltage supply pad connected to a first location of a base film;
providing a measurement pad connected to a second location of the base film;
measuring a voltage drop between the voltage supply pad and the measurement pad;
measuring a current between the voltage supply pad and the measurement pad; and
dividing the voltage drop with the current to determine a resistance.

17. The system of claim 16 wherein the determining the sheet resistance further comprises:
determining dimensions of the base film; and
dividing the resistance with an aspect ratio associated with the dimensions.

18. The system of claim 11 wherein the estimating the quiescent current further comprises determining a transistor beta for the BJT based on a correlation between the transistor beta and the sheet resistance.

19. The system of claim 11 wherein the estimating the quiescent current further comprises dividing the sheet resistance with a resistor configured to provide a base current to the BJT.

20. A sheet resistance determination module comprising:
a packaging substrate;
a power amplifier die implemented on the packaging substrate, wherein the power amplifier die includes:
a power amplifier, the power amplifier a bipolar junction transistor (BJT);
a voltage supply pad coupled to a first location of a base of the BJT, the voltage supply pad configured to apply a first voltage to the first location; and
a measurement pad coupled to a second location of the base, the measurement pad configured to measure a second voltage that is the first voltage minus a resistance multiplied by a base current.
